(19) United States
(12) Patent Application Publication
(10) Pub. No.: US 2014/0347837 A1
(43) Pub. Date: Nov. 27, 2014

(54) WIRING BOARD AND METHOD FOR MANUFACTURING THE SAME

(71) Applicant: IBIDEN CO., LTD., Ogaki-shi (JP)

(72) Inventors: Takashi KARIYA, Ogaki-shi (JP); Yoshinori Shizuno, Ogaki-shi (JP); Makoto Terui, Ogaki-shi (JP); Masatoshi Kunieda, Ogaki-shi (JP)

(73) Assignee: IBIDEN CO., LTD., Ogaki-shi (JP)

(21) Appl. No.: 14/283,337

(22) Filed: May 21, 2014

(30) Foreign Application Priority Data
May 21, 2013 (JP) 2013107178

(51) Int. Cl. H05K 1/02; H05K 3/46

(52) U.S. Cl. CPC H05K 1/0298; H05K 3/4673; H05K 3/4682
USPC 361/767; 174/251; 156/306.6; 156/247

(57) ABSTRACT

A wiring board includes multiple insulation layers including an outermost insulation layer, a first conductive pattern formed between the insulation layers, a wiring structure positioned in the outermost insulation layer and having multiple first pads such that the first pads are positioned to connect multiple terminals of a first electronic component, respectively, and multiple second pads formed on the outermost insulation layer such that the second pads are positioned to connect terminals of a second electronic component, respectively, and are set at intervals which are greater than intervals of the first pads.

### CROSS-REFERENCE TO RELATED APPLICATIONS

The present application is based upon and claims the benefit of priority to Japanese Patent Application No. 2013-107178, filed May 21, 2013, the entire contents of which are incorporated herein by reference.

### BACKGROUND OF THE INVENTION

1. Field of the Invention

The present invention relates to a wiring board and its manufacturing method.

2. Description of Background Art

A wiring board described in Published International Application WO2007/129545 has a built-in multilayer substrate where conductive patterns are formed at a finer pitch. The terminals of an electronic component to be mounted on the wiring board are electrically connected to the circuits formed in the wiring board through the built-in multilayer substrate. The entire contents of this publication are incorporated herein by reference.

### SUMMARY OF THE INVENTION

According to one aspect of the present invention, a wiring board includes multiple insulation layers including an outermost insulation layer, a first conductive pattern formed between the insulation layers, a wiring structure positioned in the outermost insulation layer and having multiple first pads such that the first pads are positioned to connect multiple terminals of a first electronic component, respectively, and multiple second pads formed on the outermost insulation layer such that the second pads are positioned to connect terminals of a second electronic component, respectively, and are set at intervals which are greater than intervals of the first pads.

According to another aspect of the present invention, a method for manufacturing a wiring board includes preparing a support board having a carrier metal foil, forming on the carrier metal foil of the support board a laminated structure including multiple insulation layers laminated one another and a first conductive pattern formed between the insulation layers, positioning in an outermost insulation layer of the insulation layers a wiring structure having multiple first pads positioned to connect multiple terminals of a first electronic component, respectively, and forming on the outermost insulation layer multiple second pads such that the second pads are positioned to connect multiple terminals of a second electronic component, respectively, and are set at intervals which are greater than intervals of the first pads.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment of the present invention;

FIG. 2 shows schematic views of pads for connection with terminals of a DRAM and an MPU;

FIG. 3 is a view showing a wiring structure;

FIG. 4 is a view illustrating a method for manufacturing a wiring structure;

FIG. 5 is a view illustrating the method for manufacturing a wiring structure;

FIG. 6 is a view illustrating the method for manufacturing a wiring structure;

FIG. 7 is a view illustrating the method for manufacturing a wiring structure;

FIG. 8 is a view illustrating the method for manufacturing a wiring structure;

FIG. 9 is a view illustrating the method for manufacturing a wiring structure;

FIG. 10 is a view illustrating the method for manufacturing a wiring structure;

FIG. 11 is a view illustrating the method for manufacturing a wiring structure;

FIG. 12 is a view illustrating a method for manufacturing a wiring board;

FIG. 13 is a view illustrating the method for manufacturing a wiring board;

FIG. 14 is a view illustrating the method for manufacturing a wiring board;

FIG. 15 is a view illustrating the method for manufacturing a wiring board;

FIG. 16 is a view illustrating the method for manufacturing a wiring board;

FIG. 17 is a view illustrating the method for manufacturing a wiring board;

FIG. 18 is a view illustrating the method for manufacturing a wiring board;

FIG. 19 is a view illustrating the method for manufacturing a wiring board;

FIG. 20 is a view illustrating the method for manufacturing a wiring board;

FIG. 21 is a view illustrating the method for manufacturing a wiring board;

FIG. 22 is a view illustrating the method for manufacturing a wiring board;

FIG. 23 is a view illustrating the method for manufacturing a wiring board;

FIG. 24 is a view illustrating the method for manufacturing a wiring board;

FIG. 25 is a view illustrating the method for manufacturing a wiring board;

FIG. 26 is a view illustrating the method for manufacturing a wiring board;

FIG. 27 is a view illustrating the method for manufacturing a wiring board;

FIG. 28 is a view illustrating the method for manufacturing a wiring board; and

FIG. 29 is a view showing a modified example of the wiring board.

### DETAILED DESCRIPTION OF THE EMBODIMENTS

The embodiments will now be described with reference to the accompanying drawings, wherein like reference numerals designate corresponding or identical elements throughout the various drawings.

A coordinate system of axes X, Y and Z crossing perpendicular to each other is used for the sake of description.

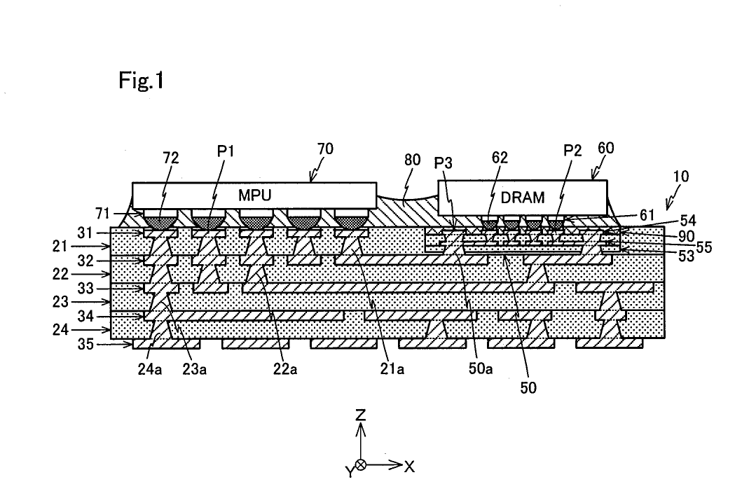

FIG. 1 is a ZX cross-sectional view showing wiring board 10 of the present embodiment along with DRAM 60 and MPU 70 mounted on wiring board 10. As shown in FIG. 1, wiring board 10 has insulation layers (21˜24) laminated in an axis Z direction, conductive pattern 31 exposed from the upper surface (on the (+Z) side surface) of insulation layer 21 positioned uppermost among insulation layers (21˜24), conductive patterns (32˜35) formed on their respective lower surfaces of insulation layers (21˜24), and wiring structure 50 positioned inside insulation layer 21.

Insulation layer 21 is positioned uppermost among insulation layers (21˜24). For insulation layer 21, interlayer insulation film (brand name: ABF-45SH, made by Ajinomoto) is used. Thus, insulation layer 21 is formed to be a layer that does not contain core material such as a glass substrate or fiberglass.

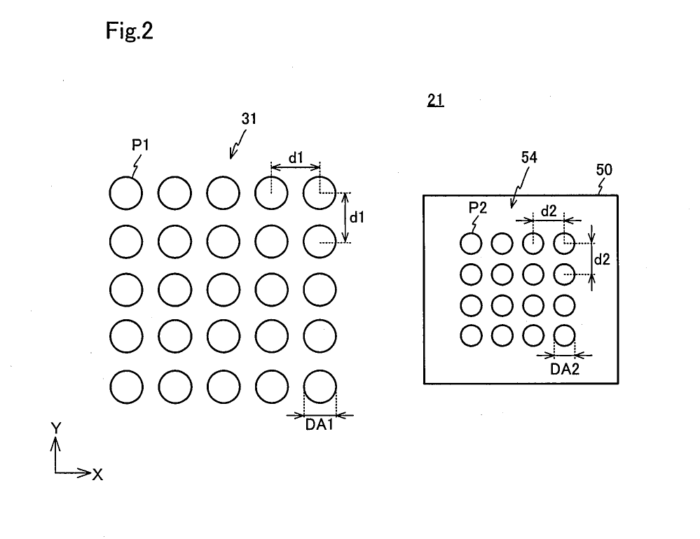

Conductive pattern 31 is formed in the upper portion of insulation layer 21, and conductive pattern 32 is formed on the lower surface of insulation layer 21. Conductive patterns (31, 32) are made of copper with a thickness of 5˜20 μm. Conductive pattern 31 is formed in a predetermined pattern. FIG. 2 schematically shows circular pad (P1) for connection with terminal 71 of MPU 70 and circular pad (P2) for connection with terminal 61 of DRAM 60. In the present embodiment, conductive pattern 31 is patterned so that portions of conductive pattern 31 form multiple pads (P1) arrayed in a matrix, as shown in FIG. 2. When MPU 70 is mounted on wiring board 10, multiple terminals of MPU 70 are connected to their respective pads (P1).

Conductive pattern 32 is also formed in a predetermined pattern. Conductive pattern 32 is connected to conductive pattern 31 by vias (21a) formed in insulation layer 21. Via (50a) is formed through insulation layer 21 and insulation layer 53. Conductive pattern 32 is also connected to conductive pattern 55 of wiring structure 50 by vias (50a).

Insulation layers (22˜24) are laminated in that order on the lower surface of insulation layer 21. Insulation layers (22˜24) are also made of interlayer insulation film the same as insulation layer 21.

Conductive patterns (33˜35) are formed on their respective lower surfaces of insulation layers (22˜24). Conductive patterns (33˜35) are also made of copper with a thickness of 5˜20 μm, the same as conductive patterns (31, 32), and are formed in their respective predetermined patterns.

Conductive pattern 33 is connected to conductive pattern 32 by vias (22a) formed in insulation layer 22. Also, conductive pattern 34 is connected to conductive pattern 33 by vias (23a) formed in insulation layer 23. Conductive pattern 35 is connected to conductive pattern 34 by vias (24a) formed in insulation layer 24.

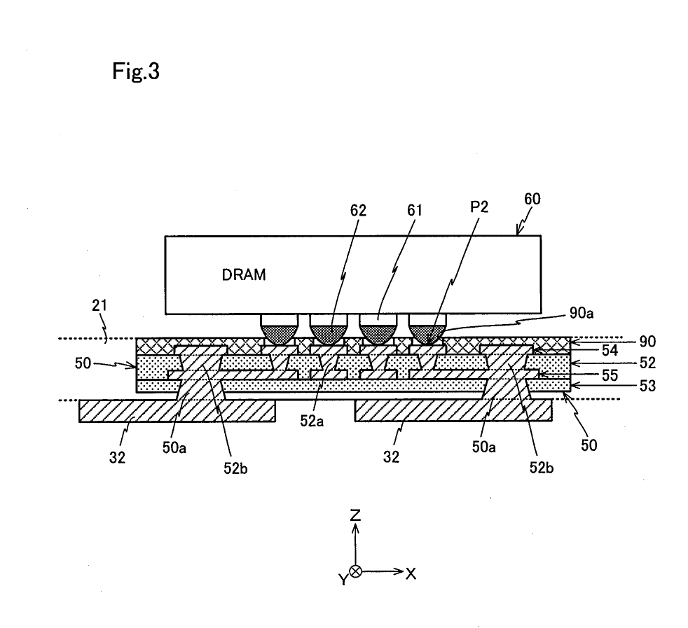

FIG. 3 is a view showing wiring structure 50 positioned in insulation layer 21. As shown in FIG. 3, wiring structure 50 is embedded in insulation layer 21 from above insulation layer 21 (from the (+Z) side). Wiring structure 50 is a multilayer substrate formed by alternately laminating an insulation layer and a conductive pattern, and has insulation layers (52, 53) and conductive patterns (54, 55).

Insulation layer 52 is made of interlayer insulation film (brand name: ABF-45SH, made by Ajinomoto) or the like. Conductive pattern 54 is formed on the upper surface of insulation layer 52. Insulation layer 53 is made of the same insulative material as for insulation layer 52, and conductive pattern 55 is formed on its upper surface. Conductive pattern 54 and conductive pattern 55 are insulated from each other by insulation layer 52.

Conductive pattern 54 on the upper surface of insulation layer 52 is formed in such a way that portions of conductive pattern 54 are set as multiple pads (P2) arrayed in a matrix as shown in FIG. 2. When DRAM 60 is mounted on wiring board 10, multiple terminals 61 of DRAM 60 are connected to their respective pads (P2).

In wiring board 10, outer diameter (DA2) of pad (P2) on which DRAM 60 is mounted is made smaller than outer diameter (DA1) of pad (P1) on which MPU 70 is mounted as shown in FIG. 2. In addition, alignment intervals (d2) of pads (P2) are set smaller than alignment intervals (d1) of pads (P1). Namely, in wiring board 10, alignment of pads (P2) for connection with terminals 61 of DRAM 60 is made finer.

In addition, in wiring board 10, surfaces of pads (P1, P2) are each coated with Ni/Pd/Au plating or Ni/Au plating. Accordingly, an increase in contact resistance caused by deterioration of surfaces of pads (P1, P2) is suppressed.

Referring to FIG. 3 again, conductive pattern 55 positioned between insulation layers 52 and 53 is formed in a predetermined pattern. Then, conductive pattern 55 is connected to pads (P2) by vias (52a) formed in insulation layer 52. In addition, by vias (52b), conductive pattern 55 is also connected to portions of conductive pattern 54 which are not pads (P2). Moreover, conductive pattern 55 is connected to conductive pattern 32 by vias (50a) which penetrate through insulation layer 53. The line and space (L/S) of conductive patterns (54, 55) is substantially 1. Then, in the present embodiment, the width of a signal line that forms conductive patterns (54, 55) is approximately 1 μm˜5 μm, and alignment intervals of signal lines are 1 μm˜5 μm. The diameter of via (52a) is approximately 1 μm˜10 μm.

Referring to FIG. 1 again, MPU 70 to be mounted on wiring board 10 is a BGA (ball grid array) type element. On the lower surface of MPU 70, terminal 71 is formed at a position facing a pad (P1) as shown in FIG. 2. Then, solder ball 72 is formed on each terminal 71. Terminal 71 of MPU 70 is adhered to pad (P1) by the solder of solder ball 72 as shown in FIG. 1. Accordingly, MPU 70 is mounted on wiring board 10.

DRAM 60 is also a BGA-type element the same as MPU 70. On the lower surface of DRAM 60, terminal 61 is formed at a position facing a pad (P2) shown in FIG. 2. Then, solder ball 62 is formed on each terminal 61. Terminal 61 is adhered to pad (P2) by the solder of solder ball 62. Accordingly, DRAM 60 is mounted on wiring board 10.

In a space between wiring board 10 and MPU 70 and DRAM 60 mounted on a surface of wiring board 10, resin 80 as underfill material is filled. Pads (P1, P2) of wiring board 10 and terminal 71 of MPU 70 as well as terminal 61 of DRAM 60 are covered and protected by resin 80.

Next, an example of a manufacturing method of wiring structure 50 structured as described above is described below.

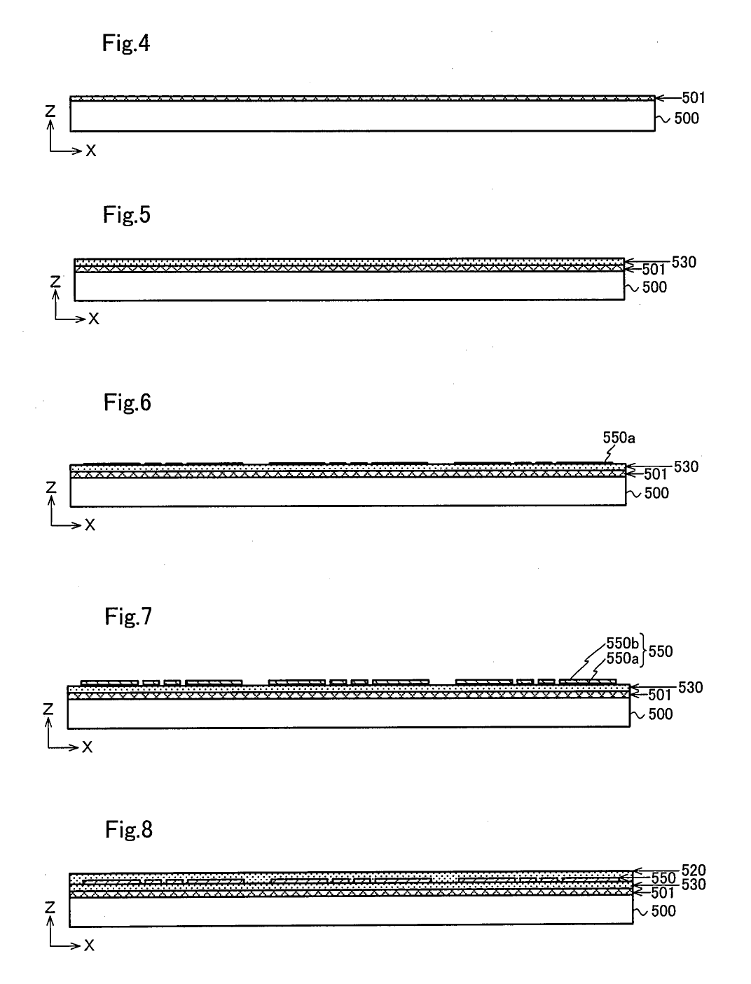

First, support plate 500 as shown in FIG. 4 is prepared. Support plate 500 is glass with a flat upper surface (the (+Z) side surface). Then, removable layer 501 is formed by applying a remover on the upper surface of support plate 500. As for a remover, WaferBOND made by Brewer Science, Inc. may be used.

Next, as shown in FIG. 5, insulative sheet 530 made of resin is positioned on removable layer 501. Then, heat is applied to removable layer 501 and insulative sheet 530 to adhere removable layer 501 and insulative sheet 530 to each other.

Next, using a semi-additive method (SAP), conductive pattern 550 is formed on the upper surface of insulative sheet 530.

In particular, first, Ti and Cu, for example, are sputtered in that order on the upper surface of insulative sheet 530 to form first metal layer (550a) made of a Ti layer and a Cu layer on the upper surface of insulative sheet 530 as shown in FIG. 6. First metal layer (550a) is for adhering insulative sheet 530 and a plated film to be laminated on first metal layer (550a).

In the above, first metal layer (550a) may also be formed by sputtering Cr and Ni in that order, or by sputtering Ta and Cu in that order.

Next, electroless copper-plated film is formed on the upper surface of first metal layer (550a) and then electrolytic copper-plated film is formed on the upper surface of the electroless copper-plated film so that double-layered second metal layer (550b) made of electroless copper-plated film and electrolytic copper-plated film is formed on the upper surface of first metal layer (550a) as shown in FIG. 7. Accordingly, double-layered conductive pattern 550 made of first metal layer (550a) and second metal layer (550b) is formed.

As structured above, signal lines that form conductive pattern 550 are set to be high density according to wiring rules of semiconductor elements such as ICs (Integrated Circuits) and LSIs (Large-Scale Integrated Circuits). In the present embodiment, the width of a signal line that forms conductive pattern 550 is approximately 1 μm˜5 μm. Also, alignment intervals of signal lines are 1 μm˜5 μm.

As shown in FIG. 8, insulative sheet 520 is positioned on the upper surface of insulative sheet 530. Then, heat is applied to insulative sheet 520 while pressure is exerted on insulative sheet 530 so that insulative sheet 520 and insulative sheet 530 are integrated.

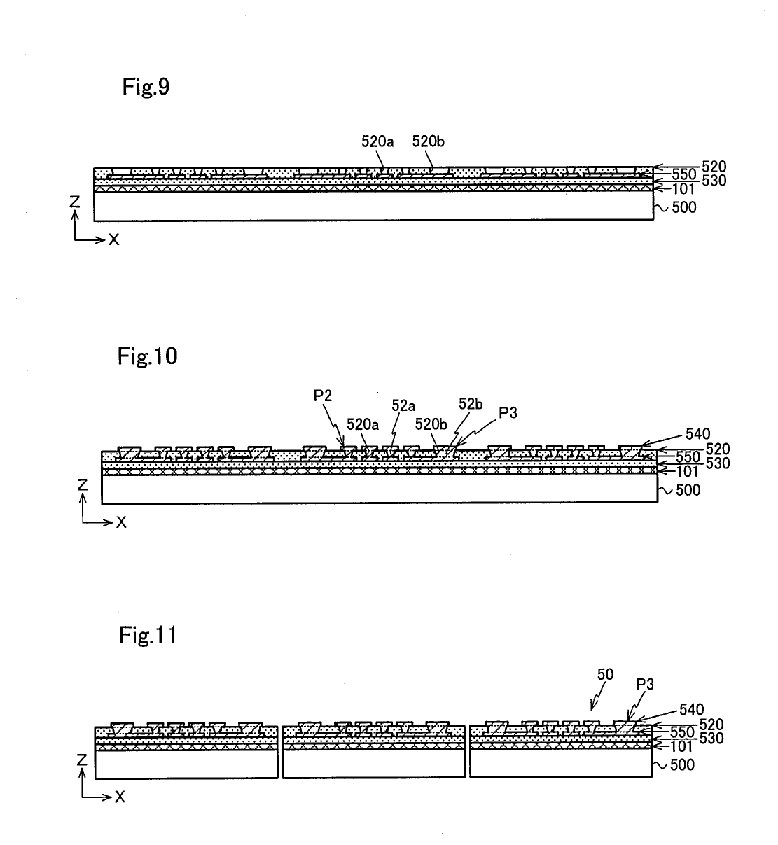

A mask with exposed portions for forming via holes (520a, 520b) is placed on the upper surface of insulative sheet 520, and insulative sheet 520 is exposed to light and then developed. Accordingly, via holes (520a, 520b) are formed in insulative sheet 520 as shown in FIG. 9. Via holes (520a, 520b) penetrate through insulative sheet 520, and portions of conductive pattern 550 are exposed from via holes (520a, 520b). The diameter of via holes (520a, 520b) formed in insulative sheet 520 is approximately 1 μm or greater and10 μm or less.

Using a semi-additive method (SAP), vias (52a, 52b) are respectively formed in via holes (520a, 520b) while conductive pattern 540 is formed on the upper surface of insulative sheet 520 as shown in FIG. 10. In conductive pattern 540, 16 pads (P2) are formed for connection with terminals 61 of DRAM 60. Pad (P2) is electrically connected to conductive pattern 550 through via (52a). Also, via (52b) and conductive patterns (540, 550) form circular pad (P3). The thickness of pad (P3) is approximately 5 μm.

In the present embodiment, the same as a signal line that forms conductive pattern 550, the width of a signal line that forms conductive pattern 540 is approximately 1 μm˜5 μm. Also, alignment intervals of signal lines are 1 μm˜5 μm.

Using a dicing saw, for example, insulative sheets (520, 530) and the like are cut along with support plate 500. Accordingly, wiring structure 50 supported by support plate 500 is completed as shown in FIG. 11. The aforementioned insulation layers (52, 53) of wiring structure 50 are formed by insulative sheets (520, 530). Also, the aforementioned conductive patterns (54, 55) of wiring structure 50 are formed by conductive patterns (540, 550).

In the present embodiment, support plate 500 made of glass with a flat surface is used for manufacturing wiring structure 50. Thus, wiring structure 50 with a smaller degree of warping is obtained.

A manufacturing method of the aforementioned wiring board 10 is described.

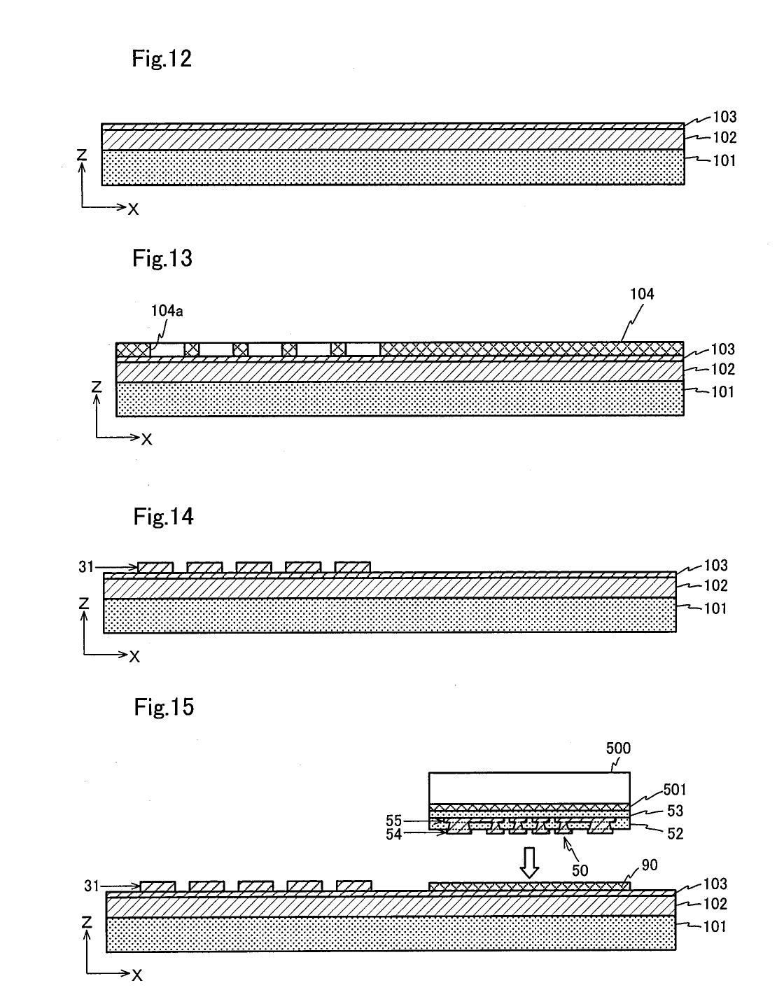

First, as shown in FIG. 12, support plate 101 is prepared, having carrier copper foil 102 and copper foil 103 on its upper surface (+Z side surface). As for support plate 101, an epoxy-resin substrate containing glass cloth as core material (prepreg with core material) and the like is used.

Next, a photosensitive dry film is laminated on the surface of copper foil 103. Then, a mask film with a predetermined pattern is adhered to the photosensitive dry film, which is then exposed to UV rays. Then, the photosensitive dry film is developed using an alkaline solution. Accordingly, plating resist 104 with openings (104a) to expose portions for forming conductive pattern 31 is formed as shown in FIG. 13.

By performing electrolytic plating on the upper surface of copper foil 103 formed on the upper surface of support plate 101, a plated film is formed. Then, plating resist 104 is removed by a solution containing monoethanolamine or the like. By so doing, conductive pattern 31 is formed on the upper surface of copper foil 103 as shown in FIG. 14. Conductive pattern 31 includes 25 pads (P1) arrayed in a matrix as shown in FIG. 2.

As shown in FIG. 15, an adhesive agent is applied on the upper surface of copper foil 103 formed on support plate 101 to form adhesive layer 90. As for an adhesive agent, for example, an epoxy-resin-based, acrylic-resin-based or silicone-resin-based adhesive agent or the like may be used. Adhesive layer 90 is formed to be substantially the same size as wiring structure 50.

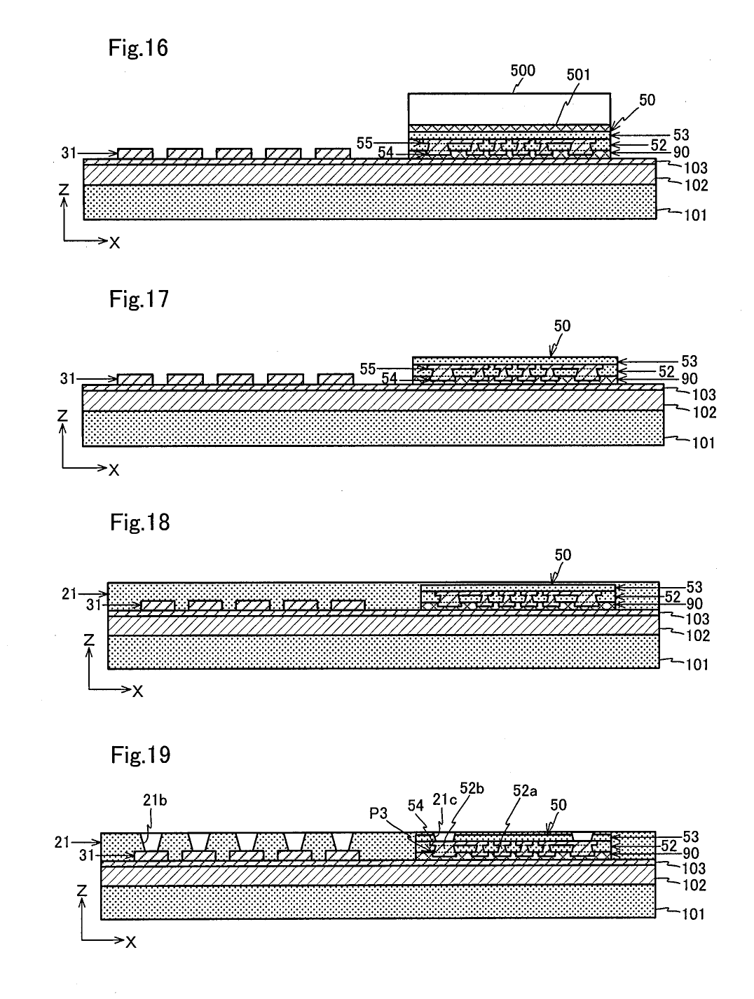

As shown in FIGS. 15 and 16, on the upper surface of adhesive layer 90, wiring structure 50 with insulation layer 52 and conductive pattern 54 facing the (−Z) side is adhered. Wiring structure 50 is integrated with support plate 500 provided in its manufacturing process. In wiring structure 50, the outer diameter of vias (52a, 52b) increases in the (+Z) direction in FIG. 1.

As shown in FIG. 17, support plate 500 integrated with wiring structure 50 is removed from wiring structure 50. To remove support plate 500, heat is applied to wiring structure 50 and support plate 500. Accordingly, removable layer 501 starts softening. Then, when removable layer 501 is fully softened, support plate 500 is removed from wiring structure 50 and the residual remover on wiring structure 50 is removed.

As shown in FIG. 18, an insulative resin interlayer material is positioned on the upper surfaces of conductive pattern 31 and wiring structure 50 and then pressure is exerted thereon. Accordingly, insulation layer 21 is formed covering conductive pattern 31 and wiring structure 50. As for insulative resin interlayer material, prepreg with core material or interlayer insulation film (brand name: ABF-45SH, made by Ajinomoto) or the like may be used.

Laser light is irradiated from a CO2 laser at insulation layer 21 to form via holes (21b, 21c) as shown in FIG. 19. Via hole (21b) is a hole penetrating through insulation layer 21 and reaching conductive pattern 31, and via hole (21c) is a hole penetrating through insulation layer 21 and insulation layer 53 of wiring structure 50 and reaching pad (P3) of wiring structure 50. The inner diameter of those via holes (21b, 21c) increases in the (+Z) direction in FIG. 19. Since the substrate is inverted to be upside down in FIG. 1, the outer diameter of vias (21a, 50a) formed in via holes (21b, 21c) decreases in the (+Z) direction.

In wiring structure 50 of the present embodiment, the diameter of via (52b) of pad (P3) is greater than the diameter of via (52a). Thus, when via hole (21c) is formed to penetrate through insulation layer 53 of wiring structure 50, penetration of laser light through conductive pattern 54 of pad (P3) is effectively avoided. Especially, since insulation layers (52, 53) and conductive patterns (54, 55) of wiring structure 50 are thinner, compared with insulation layers (21˜24) and conductive patterns (31˜35), yield of wiring structure 50 is significantly enhanced by pad (P3) formed in wiring structure 50. After via holes (21b, 21c) are formed, desmearing is performed to remove smears remaining in via holes (21b, 21c).

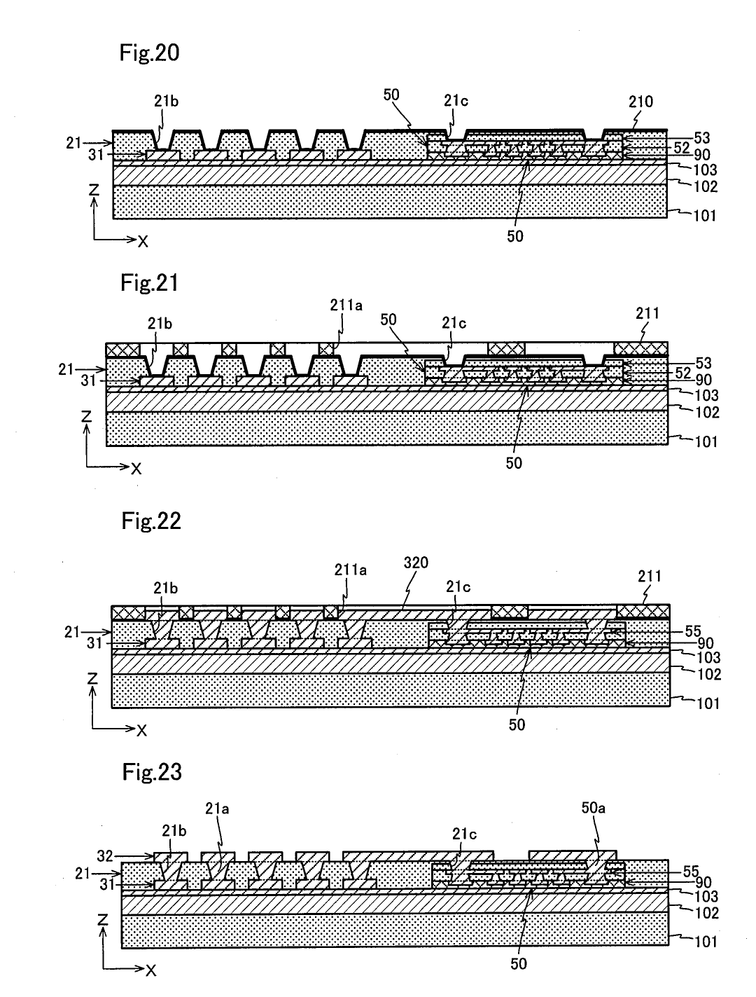

Next, support plate 101 with insulation layer 21 formed thereon is immersed in a catalyst solution containing Pd or the like as a main component so that a catalyst is attached on the surface of insulation layer 21. Then, support plate 101 is immersed in an electroless copper plating solution. Accordingly, as shown in FIG. 20, electroless plated film 210 is formed on the surface of insulation layer 21 and on the inner walls of via holes (21b, 21c). Copper, nickel or the like may be used as the material for the electroless plated film.

A photosensitive dry film is laminated on the surface of electroless plated film 210. Then, after a mask film with a predetermined pattern is adhered to the photosensitive dry film, the photosensitive dry film is exposed to UV rays. Then, the photosensitive dry film is developed using an alkaline solution. Accordingly, plating resist 211 with openings (211a) for exposing portions to form conductive pattern 32 is formed.

Electrolytic plating is performed using electroless plated film 210 formed on the upper surface of insulation layer 21 as a seed layer so that plated film 320 is formed on the surface of electroless plated film 210 as shown in FIG. 22. Then, plating resist 211 is removed, and electroless plated film 210 that was covered by plating resist 211 is removed by etching. Accordingly, conductive pattern 32 is formed to have a pattern as shown in FIG. 23. Conductive pattern 32 is connected to conductive pattern 31 by vias (21a) made of copper plating filled in via holes (21b). Also, conductive pattern 32 is connected to conductive pattern 55 of wiring structure 50 by vias (50a) made of copper plating filled in via holes (21c).

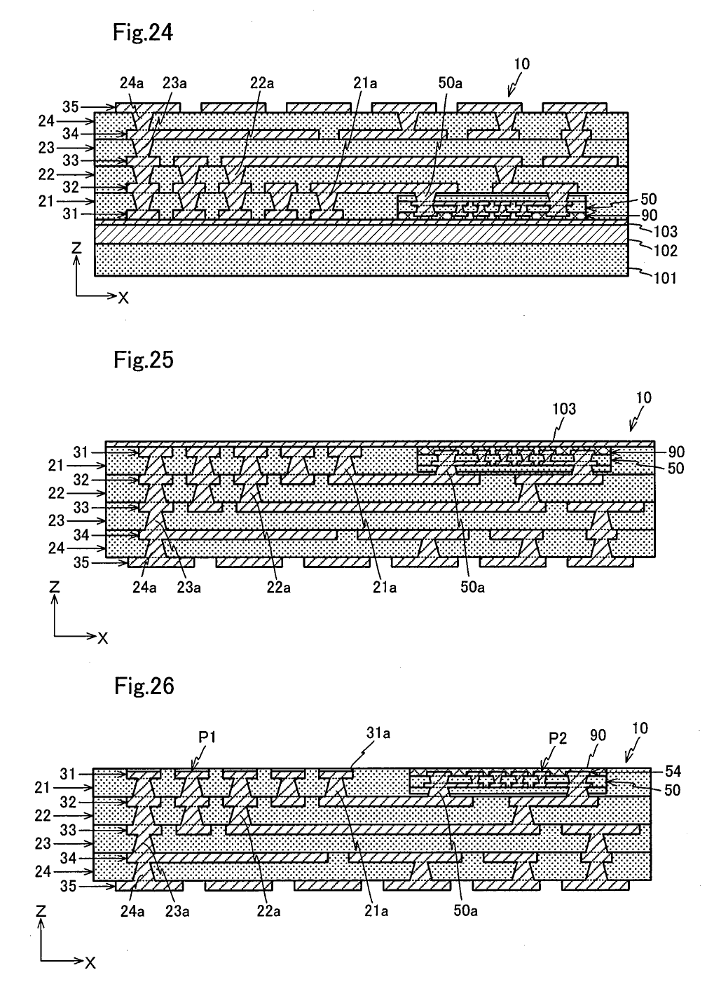

Insulation layers (22˜24) laminated on insulation layer 21 are formed consecutively by the same procedure employed for the aforementioned insulation layer 21. Also, conductive patterns (33˜35) are formed consecutively by the same procedure employed for the aforementioned conductive pattern 32. Accordingly, as shown in FIG. 24, insulation layers (21˜24) and conductive patterns (31˜35) are laminated, and wiring board 10 is formed on support plate 101.

Support plate 101 and carrier copper foil 102 are removed from wiring board 10, and wiring board 10 is inverted to be upside down as shown in FIG. 25. Then, copper foil 103 is removed by etching. Accordingly, pad (P1) that is part of conductive pattern 31 is exposed from opening (31a) as shown in FIG. 26. Also, adhesive layer 90 that adhered wiring structure 50 to copper foil 103 is exposed.

When copper foil 103 is etched, pad (P1) is etched until the surface of pad (P1) is positioned on substantially the same plane as the surface of pad (P2).

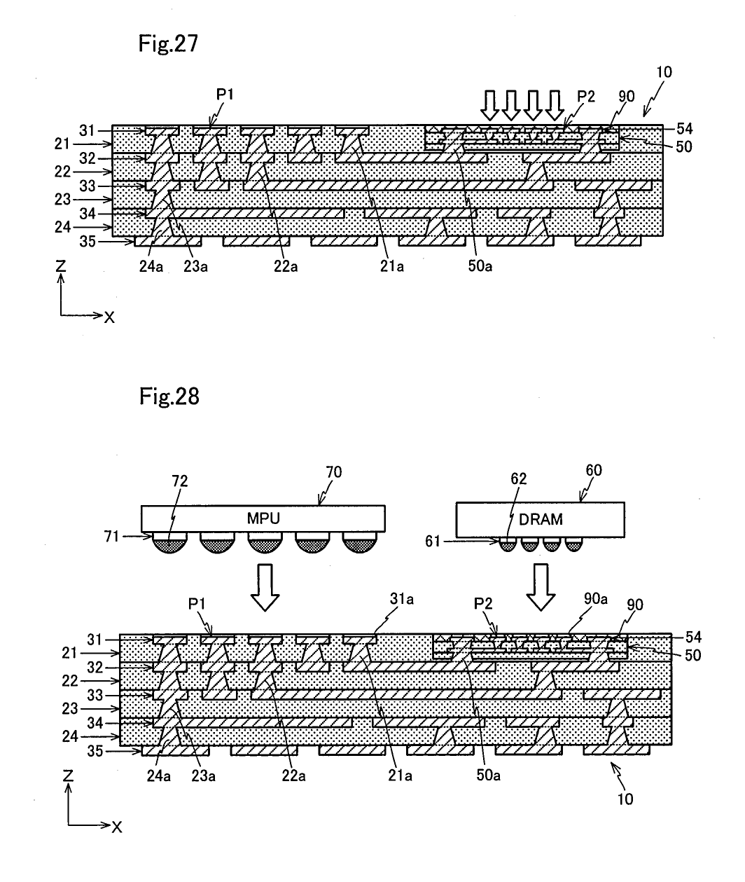

As arrows in FIG. 27 show, by irradiating laser light from a CO2 laser at adhesive layer 90 covering the surface of wiring structure 50, adhesive layer 90 covering pad (P2) of conductive pattern 54 is removed and opening (90a) is formed as shown in FIG. 28. Accordingly, pad (P2) that is part of conductive pattern 54 is exposed from opening (90a).

Coating film made of Ni/Pd/Au plating or Ni/Au plating is formed on the surface of pad (P1) exposed from insulation layer 21 of wiring board 10 and on the surface of pad (P2) exposed from adhesive layer 90.

DRAM 60 and MPU 70 are mounted on wiring board 10 structured as above, and resin 80 is filled between DRAM 60, MPU 70 and wiring board 10 to cover the connecting portions of DRAM 60, MPU 70 and wiring board 10. Accordingly, wiring board 10 shown in FIG. 1 is completed. In wiring board 10, outer diameters of via (21a) and via (50a) formed respectively in insulation layer 21 and insulation layer 53 decrease toward DRAM 60 and MPU 70, and outer diameters of via (52a) and via (52b) formed in wiring structure 50 increase toward DRAM 60 and MPU 70.

As described so far, in wiring board 10 of the present embodiment, wiring structure 50 with pad (P2) for connection with DRAM 60 is provided in uppermost insulation layer 21 of wiring board 10 as shown in FIG. 1. Thus, as shown in FIG. 2, outer diameter (DA2) of pad (P2) of wiring structure 50 is set smaller than outer diameter (DA1) of pad (P1) for connection with MPU 70, and alignment intervals (d2) of pads (P2) are set smaller than alignment intervals (d1) of pads (P1). Accordingly, without setting all of conductive patterns (31˜35) of wiring board 10 to be finer, conductive patterns (54, 55) of the portion where DRAM 60 is to be mounted are made finer. Therefore, the cost of manufacturing wiring board 10 is reduced compared with a wiring board in which all the wiring is set finer. That being the case, the cost of manufacturing a unit made of electronic components mounted on wiring board 10 is reduced.

In the present embodiment, wiring structure 50 is aligned with respect to insulation layer 21 so that pad (P2) of wiring structure 50 and pad (P1) of insulation layer 21 are positioned on substantially the same plane. Accordingly, wiring structure 50 is positioned inside uppermost insulation layer 21 of wiring board 10, and pad (P2) and pad (P1) are positioned on substantially the same plane. Thus, when MPU 70 and DRAM 60 are mounted, those electronic components are aligned accurately with respect to wiring board 10.

In wiring board 10 according to an embodiment of the present invention, DRAM 60 and MPU 70 are mounted in parallel on wiring board 10. Thus, compared with a wiring board where DRAM 60 and MPU 70 are vertically positioned, the thickness of a unit made of wiring board 10, DRAM 60 and MPU 70 is made smaller. Also, even when DRAM 60 with a greater capacity is mounted, the thickness of the entire unit is made smaller.

In wiring structure 50 of the present embodiment, the diameter of via (52b) of pad (P3) is greater than the diameter of via (52a). Then, the thickness of pad (P3) is approximately 5 μm. Therefore, when via hole (21c) is formed penetrating through insulation layer 53 of wiring structure 50, penetration of laser light through conductive pattern 54 of pad (P3) is effectively avoided.

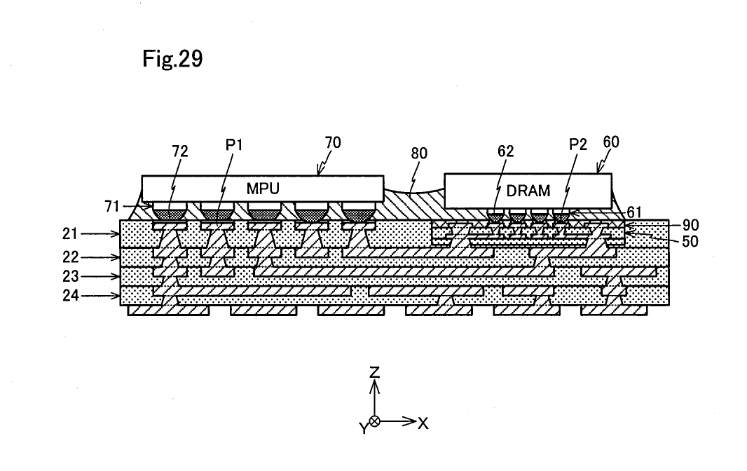

So far, an embodiment of the present invention has been described. However, the present invention is not limited to the above embodiment. For example, thicknesses of insulation layers (21˜24) are equal to each other in the embodiment as shown in FIG. 1. However, that is not the only option. The thickness of insulation layer 21 with built-in wiring structure 50 may be set greater than the thicknesses of other insulation layers (22˜24) as shown in FIG. 29. By so setting, the entire thickness of wiring board 10 with wiring structure 50 can be made thinner.

In the above embodiment, the thickness of pad (P3) of wiring structure 50 was approximately 5 μm. However, that is not the only option. The thickness of pad (P3) of wiring structure 50 may be greater than 5 μm. In such a case as well, laser light is prevented from penetrating through the insulation layer other than the layer in which to form a via hole. Namely, the thickness of pad (P3) may also be 5 μm or greater.

In the above embodiment, an example was described in which wiring board 10 has four insulation layers (21˜24). However, that is not the only option, and wiring board 10 may have three or fewer layers, or five or more layers.

In the above embodiment, an example was described in which wiring board 10 has five conductive pattern layers (31˜35). However, that is not the only option, and wiring board 10 may have four or fewer conductive pattern layers or six or more conductive pattern layers.

In the above embodiment, an example was described in which wiring structure 50 has two insulation layers (52, 53) and two conductive pattern layers (54, 55). However, that is not the only option, and wiring structure 50 may have three or more insulation layers. Also, wiring structure 50 may have three or more conductive pattern layers.

In the above embodiment, insulation layers (52, 53) of wiring structure 50 are made of interlayer insulation film (brand name: ABF-45SH, made by Ajinomoto). However, material for insulation layers of wiring structure 50 is not limited specifically. Those insulation layers may be either organic insulation layers or inorganic insulation layers.

In the above embodiment, an example was described in which pads (P1) are aligned in a matrix of five rows and five columns. However, that is not the only option, and the number of pads (P1) may be any number as long as it corresponds to the number of terminals of MPU 70 to be mounted.

In the above embodiment, an example was described in which pads (P2) are aligned in a matrix of four rows and four columns. However, that is not the only option, and the number of pads (P2) may be any number as long as it corresponds to the number of terminals of DRAM 60 to be mounted.

In the above embodiment, an example was described in which coating film made of Ni/Pd/Au plating or Ni/Au plating is formed on each surface of pads (P1, P2) of wiring board 10. However, that is not the only option, and surface treatment such as OSP (Organic Solderability Preservative) or the like may also be performed on surfaces of pads (P1, P2).

In the above embodiment, an example was described in which vias formed in wiring board 10 and wiring structure 50 are set as filled vias. However, that is not the only option, and vias in wiring board 10 and wiring structure 50 may be filled vias or conformal vias.

The material for insulation layers (21˜24, 52, 53) may be selected freely according to the usage purposes or the like of wiring board 10. For example, other than interlayer insulation film, FR-4 material made by impregnating resin in core material may also be used for insulation layers (21˜24, 52, 53). FR-4 material is obtained, for example, by impregnating epoxy resin in fiberglass, thermosetting the resin and molding the resin into a plate shape. Also, material for insulation layers (21˜24, 52, 53) is not limited to those, and prepreg or the like may also be used. Prepreg is obtained, for example, by impregnating fiberglass or aramid fiber with epoxy resin, polyester resin, bismaleimide triazine resin (BT resin), imide resin (polyimide), phenol resin, allyl polyphenylene ether resin (A-PPE resin) or the like.

In the above embodiment, support plate 500 made of glass with a flat upper surface was used for manufacturing wiring structure 50. However, that is not the only option, and silicon (Si) substrate, FR-4 substrate or the like may also be used as support plate 500.

Nickel, titanium, chromium or the like may be used as material for electroless plating. Instead of electroless plating, PVD film or CVD film may also be used.

In the same manner, nickel, titanium, chromium or the like may be used as material for electrolytic-plated film.

Plating indicates depositing conductor (such as metal) on a surface of metal or resin in a layered shape, or the deposited conductor itself (such as a metal layer). Also, plating includes wet plating such as electrolytic plating and electroless plating as well as dry plating such as PVD (Physical Vapor Deposition) and CVD (Chemical Vapor Deposition).

In addition, a method for forming conductive patterns (31˜35) and a method for patterning them are not limited specifically, and a semi-additive method, subtractive method or the like may be properly selected according to the usage purposes of wiring board 10.

In the above embodiment, DRAM 60 was listed as a semiconductor memory. However, that is not the only option, and other semiconductor memories such as SRAMs and ROMs may also be used. Also, the line and space (L/S) in conductive pattern 550 (conductive pattern 55) may be 1 μm or greater and 10 μm or less.

The surface of adhesive layer 90 covering wiring structure 50 exposed from insulation layer 21 may be positioned on substantially the same plane as the surface of insulation layer 21 into which wiring structure 50 is provided. Conductive pattern 32 electrically connecting pad (P1) and pad (P2) may also be a signal line. In addition, among laminated insulation layers (21˜24), insulation layer 21 into which wiring structure 50 is provided may be such that does not contain core material.

Unless deviating from the broader concept and scope of the present invention, numerous modifications and variations of the present invention are possible. In addition, the aforementioned embodiment describes the present invention but does not limit the scope of the present invention.

A wiring board according to an embodiment of the present invention is suitable for mounting electronic components. Also, a manufacturing method of a wiring board according to an embodiment of the present invention is suitable for manufacturing such a wiring board.

In a wiring board to be used for a smartphone or the like, an MPU (Micro Processing Unit) is usually mounted in addition to a DRAM. Thus, as terminal intervals are becoming smaller in response to an increase in the capacity of a semiconductor memory such as a DRAM as described above, the terminal intervals of a DRAM are expected to become smaller than the terminal intervals of an MPU. Therefore, in a wiring board on which a DRAM and an MPU are to be mounted, the cost of manufacturing the wiring board is thought to be suppressed from increasing by reducing only the alignment intervals of the pads to which the terminals of the DRAM are connected.

In a multilayer printed wiring board, by positioning a multilayer substrate in a portion for mounting an electronic component, an electronic component with terminals aligned at smaller intervals is mounted accurately.

Intervals of terminals in a DRAM (Dynamic Random Access Memory) mounted on a wiring board are becoming smaller in response to an increase in memory capacity. As a result, pads of a wiring board for connection with the terminals of a DRAM are to be aligned at smaller intervals.

A wiring board according to an embodiment of the present invention can suppress an increase in the cost of manufacturing a unit which is completed when electronic components are mounted on a wiring board.

A wiring board according to an embodiment of the present invention has multiple laminated insulation layers; a first conductive pattern positioned between the insulation layers; and a wiring structure in which multiple first pads are formed for connection with their respective terminals of a first electronic component and which is formed in the outermost insulation layer among the multiple insulation layers. In the insulation layer in which the wiring structure is formed, multiple second pads which are set at intervals wider than those of the first pads are formed for connection with the terminals of a second electronic component, different from the first electronic component.

A method for manufacturing a wiring board according to another embodiment of the present invention includes the following: preparing a support plate with a carrier copper foil; laminating multiple insulation layers on the carrier copper foil of the support plate; forming a first conductive pattern positioned between the insulation layers; inside the outermost insulation layer among the multiple insulation layers, providing a wiring structure having multiple first pads for connection with their respective terminals of a first electronic component; and at intervals wider than those of the first pads, forming multiple second pads for connection with the terminals of a second electronic component, different from the first electronic component, on the insulation layer with the wiring structure provided therein.

According to an embodiment of the present invention, only the alignment intervals of pads for connection with terminals of a first electronic component are set smaller, and the alignment intervals of pads for connection with terminals of a second electronic component are set at a regular pitch. Therefore, the cost of manufacturing a wiring board is suppressed from increasing.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
a plurality of insulation layers including an outermost insulation layer;
a first conductive pattern formed between the insulation layers;
a wiring structure positioned in the outermost insulation layer and having a plurality of first pads such that the plurality of first pads is positioned to connect a plurality of terminals of a first electronic component, respectively; and
a plurality of second pads formed on the outermost insulation layer such that the plurality of second pads is positioned to connect a plurality of terminals of a second electronic component, respectively, and is set at intervals which are greater than intervals of the first pads.

2. A wiring board according to claim 1, wherein the plurality of first pads in the wiring structure and the plurality of second pads on the outermost insulation layer are formed such that the plurality of first pads and the plurality of second pads are positioned substantially on a same plane.

3. A wiring board according to claim 1, further comprising:
a semiconductor memory device mounted on the wiring structure; and
a micro processing unit device mounted on the outermost insulation layer,
wherein the semiconductor memory device is the first electronic component, and the micro processing unit device is the second electronic component.

4. A wiring board according to claim 1, further comprising:
a plurality of second via conductors formed in the outermost insulation layer,
wherein the wiring structure is a multilayer substrate having the plurality of first pads, a second conductive pattern and a plurality of first via conductors connecting the plurality of first pads and the second conductive pattern, and the plurality of second via conductors in the outermost insulation layer is connecting the first conductive pattern and the plurality of second pads.

5. A wiring board according to claim 1, further comprising:
a plurality of second via conductors formed in the outermost insulation layer,
wherein the wiring structure is a multilayer substrate having the plurality of first pads, a second conductive pattern and a plurality of first via conductors connecting the plurality of first pads and the second conductive pattern, and the plurality of second via conductors in the outermost insulation layer is connecting the first conductive pattern and the second conductive pattern.

6. A wiring board according to claim 4, wherein the second conductive pattern in the wiring structure includes a plurality of third pads positioned to be connected to the plurality of second via conductors, respectively.

7. A wiring board according to claim 4, wherein each of the third pads has a thickness which is set greater than 5 μm.

8. A wiring board according to claim 4, wherein the second conductive pattern has a line and space, L/S, and has a line width and a line space set in a range of from 1 μm or greater to 10 μm or less.

9. A wiring board according to claim 4, wherein each of the second via conductors formed in the outermost insulation layer has a diameter which is decreasing toward the second electronic component, and each of the first via conductors in the wiring structure has a diameter which is increasing toward the first electronic component.

10. A wiring board according to claim 1, wherein each of the first pads and second pads has a surface subjected to an oxidation preventing treatment.

11. A wiring board according to claim 1, further comprising:
an adhesive layer formed on the wiring structure such that the adhesive layer is covering a surface of the wiring structure exposed from the outermost insulation layer, wherein the adhesive layer has a surface which is substantially on a same plane as a surface of the outermost insulation layer.

12. A wiring board according to claim 1, wherein the first conductive pattern is a signal line structure which electrically connects the plurality of first pads and the plurality of second pads.

13. A wiring board according to claim 1, wherein the outermost insulation layer has a largest thickness among the insulation layers.

14. A wiring board according to claim 1, wherein the outermost insulation layer has no glass fiber cloth.

15. A method for manufacturing a wiring board, comprising:
preparing a support board having a carrier metal foil;
forming on the carrier metal foil of the support board a laminated structure comprising a plurality of insulation layers laminated one another and a first conductive pattern formed between the insulation layers;
positioning in an outermost insulation layer of the plurality of insulation layers a wiring structure having a plurality of first pads positioned to connect a plurality of terminals of a first electronic component, respectively; and
forming on the outermost insulation layer a plurality of second pads such that the plurality of second pads is positioned to connect a plurality of terminals of a second electronic component, respectively, and is set at intervals which are greater than intervals of the first pads.

16. A method for manufacturing a wiring board according to claim 15, wherein the positioning of the wiring structure includes disposing the wiring structure with respect to the outermost insulation layer such that the plurality of first pads and the plurality of second pads are positioned substantially on a same plane.

17. A method for manufacturing a wiring board according to claim 15, further comprising:
removing the support board having the metal foil from the laminated structure.

18. A method for manufacturing a wiring board according to claim 15, further comprising:
forming a plurality of second via conductors in the outermost insulation layer,
wherein the wiring structure is a multilayer substrate having the plurality of first pads, a second conductive pattern and a plurality of first via conductors connecting the plurality of first pads and the second conductive pattern, and the plurality of second via conductors is formed such that the plurality of second via conductors connects the first conductive pattern and at least one of the plurality of second pads and the second conductive pattern.

19. A method for manufacturing a wiring board according to claim 18, wherein the second conductive pattern in the wiring structure includes a plurality of third pads positioned to be connected to the plurality of second via conductors, respectively.

20. A method for manufacturing a wiring board according to claim 15, further comprising:
applying an oxidation preventing treatment on a surface of each of the first pads and second pads.
